(19) United States
(12) Patent Application Publication
(10) Pub. No.: US 2005/0266688 A1
(43) Pub. Date: Dec. 1, 2005

(54) Semiconductor device fabrication method

(75) Inventor: Takashi Watanabe, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 10/944,949

(22) Filed: Sep. 21, 2004

(30) Foreign Application Priority Data
May 25, 2004 (JP) 2004-154229

(51) Int. Cl. H01L 21/302

(52) U.S. Cl. 438/692

(57) ABSTRACT

The semiconductor device fabrication method comprises the step of conditioning the surface of a polishing pad 104 while a liquid 126 is being fed onto the polishing pad 104; the step of spraying water 128 onto the polishing pad 104 to clean the surface of the polishing pad 104 after the conditioning of surface of the polishing pad 104 has been performed; and the step of polishing the surface of the film-to-be-polished 20 formed on a semiconductor substrate 10 while a polishing slurry 26 is being fed onto the polishing pad 104 to planarize the surface of the film-to-be-polished 20. The surface of the polishing pad 104 is cleaned after the conditioning of the polishing pad has been performed and before the surface of the film-to-be-polished 20 is polished, whereby particles which are a factor for the generation of scratches can be removed from the surface of the polishing pad 104 without failure. Thus, the generation of scratches in the surface of the film-to-be-polished 20 can be suppressed.

### CROSS-REFERENCE TO RELATED APPLICATION

This application is based upon and claims priority of Japanese Patent Application No. 2004-154229, filed on May 25, 2004, the contents being incorporated herein by reference.

### BACKGROUND OF THE INVENTION

The present invention relates to a semiconductor device fabrication method, more specifically a semiconductor device fabrication method for polishing a film-to-be-polished.

As a technique for forming device isolation regions for defining device regions, LOCOS (LOCal Oxidation of Silicon) has been conventionally known.

However, when device regions are formed by LOCOS, the device regions tend to be decreased due to bird's beaks. When device regions are formed by LOCOS, large steps are formed on a surface of a substrate. The technique of forming device isolation regions by LOCOS has made further micronization and integration increase difficult.

As a technique taking over the LOCOS, STI (Shallow Trench Isolation) is noted. The method for forming device isolation regions by STI will be explained with reference to FIGS. 20A to 20C. FIGS. 20A to 20C are sectional views of a semiconductor device in the steps of the conventional semiconductor device fabrication method.

As illustrated in FIG. 20A, a silicon oxide film 212 and a silicon nitride film 214 are sequentially formed on a semiconductor substrate 210.

Next, the silicon oxide film 212 and the silicon nitride film 214 are patterned by photolithography to form openings 216 in the silicon nitride film 214 and the silicon oxide film 212 down to the semiconductor substrate 210.

By using as the mask the silicon nitride film 214 with the openings 216 formed in, the semiconductor substrate 210 is anisotropically etched. Thus, trenches 218 are formed in the semiconductor substrate 210.

As illustrated in FIG. 20B, a silicon oxide film 220 is formed in the trenches 218 and on the silicon nitride film 214.

As illustrated in FIG. 20C, the surface of the silicon oxide film 220 is polished by CMP (Chemical Mechanical Polishing) until the surface of the silicon nitride film 214 is exposed. The silicon nitride film 214 functions as the stopper in polishing the silicon oxide film 220. The polishing slurry contains abrasive grain grains of, e.g., silica and an additive of, e.g., KOH. Thus, the device isolation regions 221 of the silicon oxide film 220 are buried in the trenches 218. The device isolation regions 221 define device regions 222.

Then, the silicon nitride film 214 and the silicon oxide film 212 are etched off. Then, transistors (not illustrated) are formed in the device regions 222. Thus, semiconductor device is fabricated.

When the device regions 221 are formed by STI, no birds' beak is generated, as when device regions are formed LOCOS, and the decrease of the device regions 222 can be prevented. The depth of the trenches 218 is set large, whereby the effective intra-device distance can be made large, and accordingly the device isolation function can be high.

Following references disclose the background art of the present invention.

[Patent Reference 1]

Specification of Japanese Patent Application Unexamined Publication No. 2003-127063

[Patent Reference 2]

Specification of Japanese Patent Application Unexamined Publication No. Hei 10-94964

[Patent Reference 3]

Specification of Japanese Patent Application Unexamined Publication No. 2000-218517

[Patent Reference 4]

Specification of Japanese Patent Application Unexamined Publication No. Hei 3-10769

[Patent Reference 5]

Specification of Japanese Patent Application Unexamined Publication No. Hei 10-202502

[Patent Reference 6]

Specification of Japanese Patent Application Unexamined Publication No. Hei 10-225862

However, the conventional fabrication method often causes a number of scratches in the surface of a film-to-be-polished 220. Accordingly, it has been often cases that semiconductor devices cannot be fabricated with high yields.

### SUMMARY OF THE INVENTION

According to one aspect of the present invention, there is provided a semiconductor device fabrication method comprising the steps of: conditioning the surface of a polishing pad while a liquid is being fed onto the polishing pad; spraying water onto the polishing pad to clean the surface of the polishing pad after the conditioning of the surface of the polishing pad has been performed; and polishing the surface of the film-to-be-polished formed over the semiconductor substrate with the polishing pad while the polishing slurry being fed onto the polishing pad to planarize the surface of the film-to-be-polished, after the surface of the polishing pad has been cleaned.

According to the present invention, after the conditioning of the polishing pad has been performed and before the surface of a film-to-be-polished is polished, the surface of the polishing pad is cleaned by spraying deionized water at high pressure onto the polishing pad, whereby particles which are a factor for the generation of scratches can be removed from the surface of the polishing pad without failure. Thus, according to the present embodiment, the surface of the film-to-be-polished without particles remaining on the surface thereof can be polished. The present invention can suppress the generation of scratches in the surface of a film-to-be-polished. Accordingly, the present invention can increase the yield of semiconductor device fabrication.

### BRIEF DESCRIPTION OF THE DRAWINGS

FIG. 1 is a plan view of the polishing machine.

FIG. 2 is a side view of a part of the polishing machine illustrated in FIG. 1.

FIG. 3 is an enlarged side view of a part of the polishing machine illustrated in FIG. 1.

FIGS. 4A to 4C are sectional views of a semiconductor device in the steps of the semiconductor device fabrication method according to a first embodiment of the present invention (Part 1).

FIGS. 5A and 5B are sectional views of a semiconductor device in the steps of the semiconductor device fabrication method according to the first embodiment of the present invention (Part 2).

FIGS. 6A and 6B are side views of the polishing machine, which explain the semiconductor device fabrication method according to the first embodiment of the present invention (Part 1).

FIGS. 7A and 7B are side views of the polishing machine, which explain the semiconductor device fabrication method according to the first embodiment of the present invention (Part 2).

FIG. 8 is side view of the polishing machine, which explain the semiconductor device fabrication method according to the first embodiment of the present invention (Part 3).

FIGS. 9A and 9B are sectional views of the polishing pad, which illustrate states of the polishing pad.

FIG. 10 is a graph of the characteristics of the polishing slurry used in the first embodiment of the present invention.

FIGS. 11A and 11B are conceptual views of the mechanism for changing the polishing rate.

FIG. 12 is a graph conceptually showing changes of the drive voltage or the drive current of the polishing table.

FIG. 13 is a graph of the number of scratches made in the surface of the film-to-be-polished (Part 1).

FIG. 14 is a graph of intra-plane distribution of the polished amount of the film-to-be-polished.

FIGS. 15A and 15B are sectional views of a semiconductor device in the steps of the semiconductor device fabrication method according to Modification 1 of the first embodiment of the present invention (Part 1).

FIG. 16 is a sectional view of a semiconductor device in the steps of the semiconductor device fabrication method according to Modification 1 of the first embodiment of the present invention (Part 2).

FIGS. 17A and 17B are sectional views of a semiconductor device in the steps of the semiconductor device fabrication method according to Modification 2 of the first embodiment of the present invention (Part 2).

FIG. 18 is a side view of the polishing machine, which explains the semiconductor device fabrication method according to a second embodiment of the present invention.

FIG. 19 is a graph of the number of scratches made in the surface of the film-to-be-polished (Part 2).

FIGS. 20A and 20B are sectional views of a semiconductor device in the steps of the conventional semiconductor device fabrication method, which explain the method.

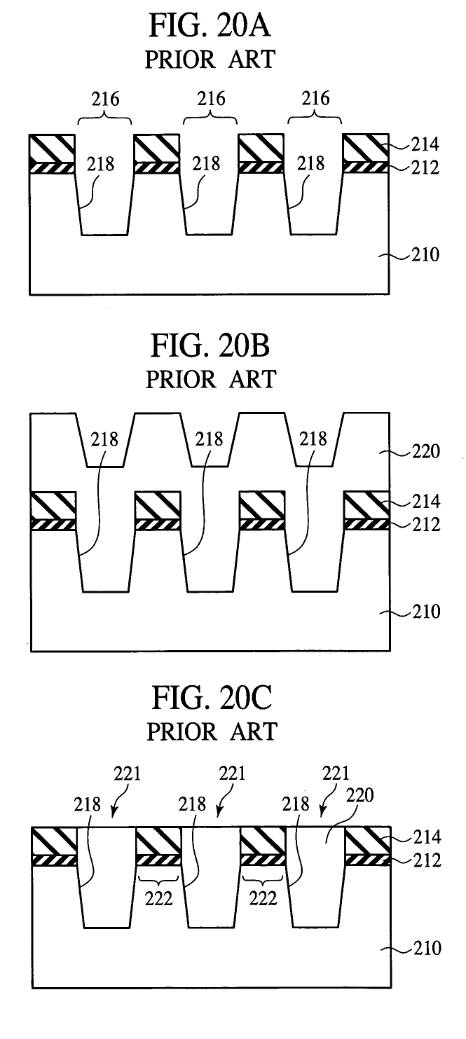

### DETAILED DESCRIPTION OF THE INVENTION

### A First Embodiment

(Polishing Machine)

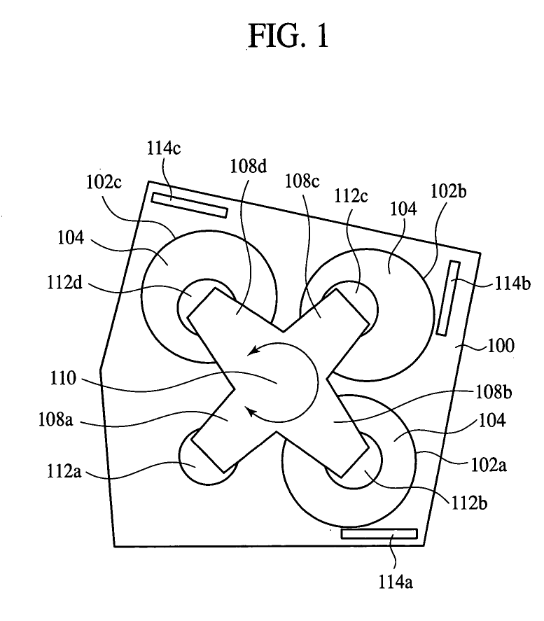

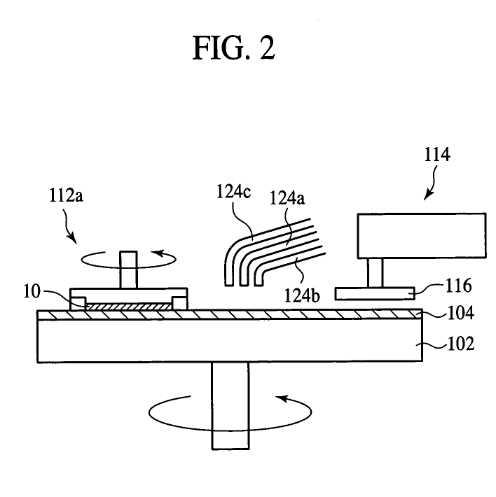

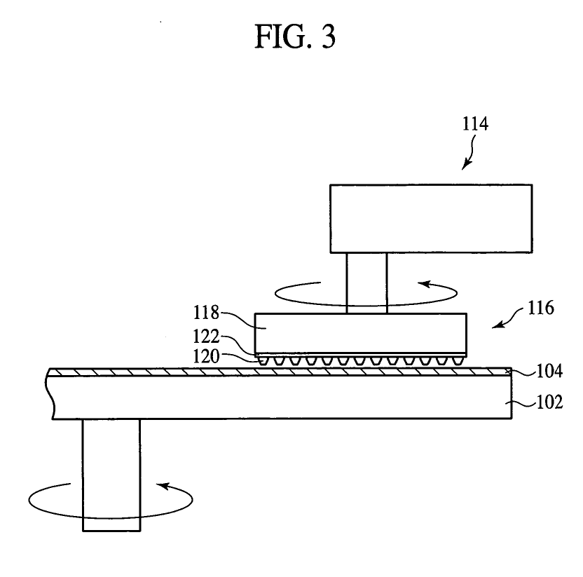

Before the semiconductor device fabrication method according to a first embodiment of the present invention is explained, the polishing machine used in the present embodiment will be explained with reference to FIGS. 1 to 3. FIG. 1 is a plan view of the polishing machine. FIG. 2 is a sectional view of a part of the polishing machine illustrated in FIG. 1. FIG. 3 is an enlarge side view of a part of the polishing machine illustrated in FIG. 1.

As illustrated in FIG. 1, three rotary polishing tables 102a-102c are disposed on a base 100.

In the present embodiment, the surface of a film-to-be-polished is polished with, e.g., the polishing table 102a. The polishing tables 102b, 102c may be used to polish the surface of the film-to-be-polished.

As illustrated in FIG. 2, polishing pads 104 are disposed respectively on the polishing tables 102a-102c. The polishing pads 104 are formed of, e.g., urethane foam.

As illustrated in FIG. 1, a carousel 110 with the arms 108a-108d is disposed on the base 100.

Rotary polishing heads 112a-112d are disposed respectively on the arms 108a-108d. The cursor 110 is suitably rotated to move the polishing heads 112a-112d.

As illustrated in FIG. 2, the polishing heads 112a-112d support semiconductor substrates (semiconductor wafers) 10. The polishing heads 112a-112d rotating the semiconductor substrates 10, pressing the semiconductor substrates 10 against the polishing pads 104.

A plurality of nozzles 124a, 124b, 124c are disposed above the polishing tables 102a-102c. The nozzle 124a for feeding a polishing slurry onto the polishing pad 104. The nozzles 124b is for feeding deionized water onto the polishing pad 104. The nozzle 124c is for spraying deionized water at high pressure onto the polishing pad 104. The forward end of the nozzles 124c is so configured that the deionized water is spread all over the polishing pad 104. Thus, the deionized water can be fed quickly to the entire surface of the polishing pad 104, and the surface of the polishing pad 104 can be cleaned without failure.

As illustrated in FIG. 1, conditioner 114a-114c for conditioning the polishing pads 104 are disposed by the polishing tables 102a-102c.

As illustrated in FIG. 3, the conditioner 114 each include a diamond disk 116. Each diamond disk 116 includes a base 118 of, e.g., stainless steel, and granular diamonds 120 of, e.g., 150 μm fixed to the base 118. The diamonds 120 are arranged in several particles to several tens particles per 1 mm². The diamonds 120 are fixed to the base 118 by, e.g., a nickel plated layer 122.

Thus, the polishing machine used in the present embodiment is constituted.

(The Semiconductor Device Fabrication Method)

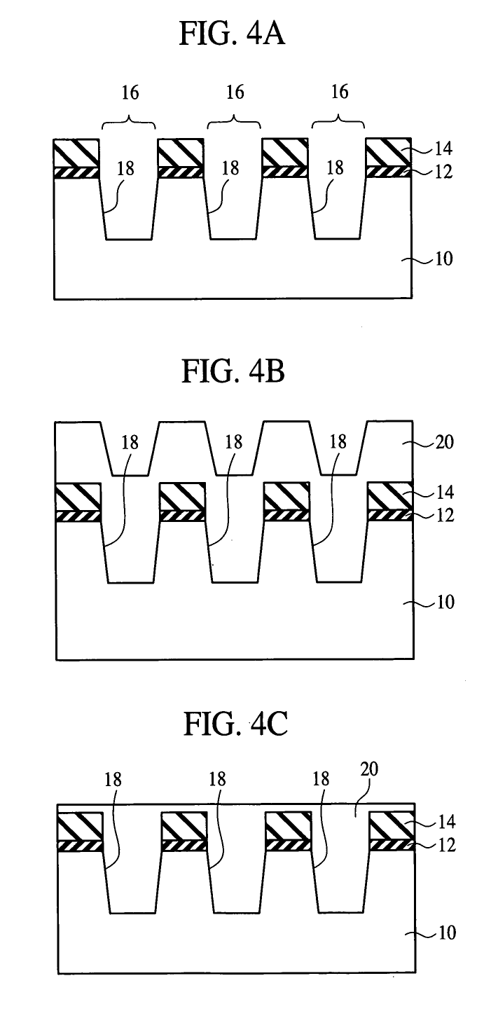

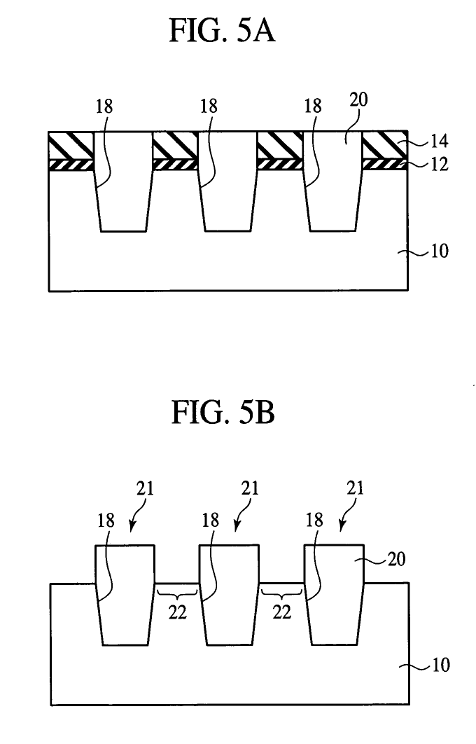

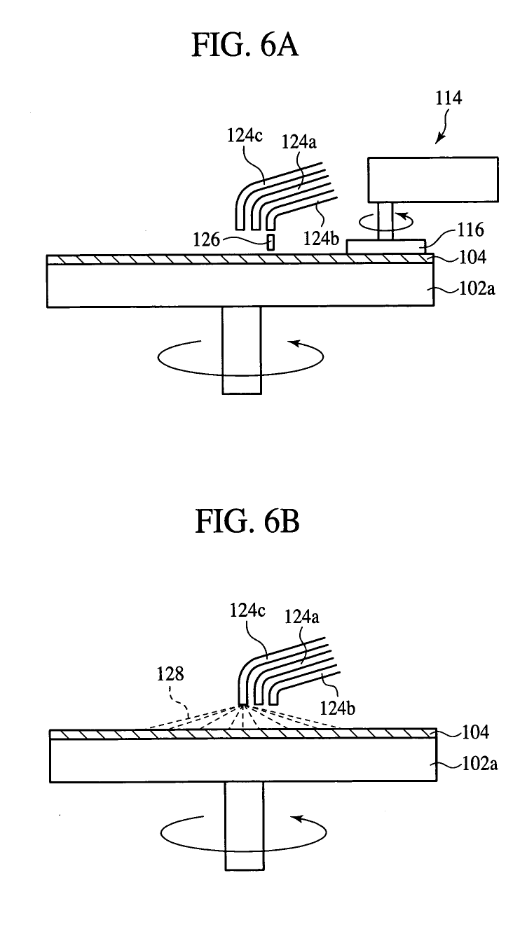

The semiconductor device fabrication method according to a first embodiment of the present invention will be explained with reference to FIGS. 4A to 12. FIGS. 4A to 5B are sectional views of a semiconductor device in the steps of the semiconductor device fabrication method according to the present embodiment, which illustrate the method. FIGS. 6A to 8 are side views of the semiconductor device in the steps of the semiconductor device fabrication method, which illustrate the method.

First, a 10 nm-thickness silicon oxide film 12 is formed on a semiconductor substrate 10 of, e.g., silicon by, e.g., thermal oxidation.

Next, a silicon nitride film 14 of, e.g., an about 100 nm-thickness is formed on the entire surface by, e.g., CVD.

Next, openings 16 are formed in the silicon nitride film 14 and the silicon oxide film 12 down to the semiconductor substrate 10 by photolithography.

Then, with the silicon nitride film 14 with the openings 16 formed in, the semiconductor substrate 10 is anisotropically etched. Thus, trenches 18 are formed in the semiconductor substrate 10. The depth of the trenches 18 is, e.g., about 380 nm from the surface of the silicon nitride film 14. (see FIG. 4A).

Next, as illustrated in FIG. 4B, a silicon oxide film 20 is formed on the entire surface by, e.g., high density plasma CVD. The thickness of the silicon oxide film 20 is, e.g., 425 nm. Thus, the silicon oxide film 20 is buried in the trenches 18, and the silicon oxide film 20 has concavities and convexities in the surface. The silicon oxide film 20 is a film-to-be-polished.

Then, the semiconductor substrate 10 is supported by the polishing head 112a (see FIG. 1). At this time, the semiconductor substrate 10 is supported with the film-to-be-polished 20 faced downward.

Next, conditioning of the polishing pad 104 is performed (see FIG. 6A).

The conditioning of the polishing pad 104 is performed as follows. That is, as illustrated in FIG. 6A, while the diamond disk 116 is being rotated, the diamond disk 116 is lowered, and the lower side of the diamond disk 116 is pressed against the surface of the polishing pad 104. At this time, the polishing table 102a is rotated while deionized water 126 is fed onto the polishing pad 104 through the nozzle 124b.

Conditions for conditioning the polishing pad 104 are as exemplified below.

The supply amount of the deionized water 126 to be fed onto the polishing pad 104 when the conditioning is performed is, e.g., 0.1-0.3 liters/minute. The supply amount of the deionized water is 0.2 liters/minute here.

The load for the diamond disks 116 to apply to the polishing pad 104 is, e.g., 1.3-4.6 kgf. The load for the diamond disks 116 to apply to the polishing pad 104 is 4.1 kgf here.

The rotation number of the diamond disks 116 is, e.g., 70-120 rotations/minute. The rotation number of the diamond disk 116 is 98 rotations/minute here.

The rotation number of the polishing table 102a is, e.g., 70-120 rotations/minute. The rotation number of the diamond disk 102a is 105 rotations/minute here.

The period of time of conditioning the polishing pad 104 is, e.g., 5-120 seconds. The period of time of conditioning the polishing pad 104 is 48 seconds here.

Conditions for conditioning the polishing pad 104 are not limited to the above and may be suitably set.

Thus, the conditioning of the surface of the polishing pad 104 is completed.

After the conditioning of the polishing pad 104 is completed, the diamond disks (conditioner) 116 are lifted. Thus, the diamond disks 116 are not in contact with the polishing pad 104.

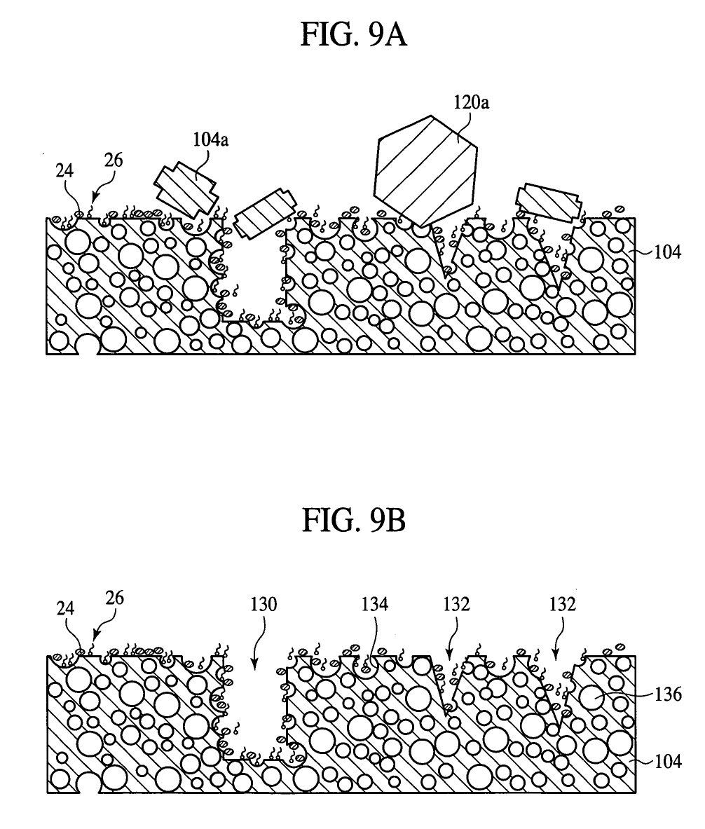

FIG. 9A is sectional views of the polishing pad at the time when the conditioning of the polishing pad has been completed.

As illustrated in FIG. 9A, abrasive grains 24, an additive 26 and cut particle 104a of the polishing pad 104, etc. adhere to the surface of the polishing pad 104. The diamond particles 120a often adhere to the surface of the polishing pad 104. The abrasive grains 24 and the additive 26 have been contained, e.g., in slurries fed onto the polishing pad 104 which have been previously polished. The diamond particles 120a are parts of the diamonds 120 provided on the diamond disks 116, which have come off the diamond disks 116. The cut particle 104a is produced by a part of the polishing pad 104 being cut by the diamonds 120. The diamond particles 120a and the cut particle 104a are factors for causing scratches (not illustrated) in the surface of the film-to-be-polished 20 when the film-to-be-polished 20 is polished.

Then, in order to remove the diamond particles 120a and the cut particle 104a, the surface of the polishing pad 104 are cleaned (see FIG. 6B).

The cleaning of the surface of the polishing pad 104 is performed as follows. That is, while the polishing table 102a is being rotated, the deionized water 128 is sprayed at high pressure onto the surface of the polishing pad 104 through the nozzle 124c. As described above, the nozzle 124c has the forward end configured so that the deionized water 128 is spread all over the polishing pad 104. The deionized water can be quickly fed to the entire polishing pad 104. Furthermore, the deionized water 128, which is sprayed under high pressure, can clean the surface of the polishing pad 104 without failure.

Conditions for cleaning the surface of the polishing pad 104 are as exemplified below.

The flow rate of the deionized water 128 is, e.g., 0.2-10 liters/minute. The flow rate of the deionized water 128 is 3 liters/minute here.

The pressure under which the deionized water 128 is sprayed is, e.g., 350-7000 gf/cm² when metered with a pressure gauge connected to a pipe of, e.g., a 7.53 mm-diameter. The pressure under which the deionized water 128 is ejected is 1750 gf/cm² here.

The sectional area of the nozzle 124c is, e.g., 10 mm² or below. The sectional area of the nozzle 124c is 2 mm² here.

The rotation number of the polishing table 102a is, e.g., 70-150 rotations/minute. The rotation number of the polishing table 102a is 105 rotations/minute here.

The period of time of ejecting the deionized water 128 is, e.g., 1-10 seconds. The period of time of spraying the deionized water is 2 seconds here.

Conditions for cleaning the surface of the polishing pad 104 are not limited to the above and may be suitably set.

FIG. 9B illustrates a state of the polishing pad at the time when the cleaning of the surface of the polishing pad has been completed.

As illustrated in FIG. 9B, diamond particles 120a and cut particle 104a, which are factors for scratches, have come off the polishing pad 104.

On the other hand, the abrasive grains 24 and the additive 26 remain in the grooves 130, 132 and cavities 134. The groves 130 have been formed in the polishing pad 104. The grooves 132 are formed by a part of the polishing pad 104 being ground by the diamonds 120 when the conditioning of the polishing pad 104 is performed. The cavities 134 are due to bubbles 136 induced in the polishing pad 104.

When the surface of the polishing pad 104 is cleaned, it is preferable that the surface of the polishing pad 104 is not so excessively cleaned that the abrasive grains 24 and the additive 26 which have remained in the grooves 130, 132 and cavities 134 in the previous polishing, are not excessively removed. For the following reason, the surface of the polishing pad 104 is cleaned under conditions which permit the abrasive grains 24 and the additive 26 remaining the grooves 130, 132 and the cavities 134 not to be excessively removed.

That is, when the surface of the polishing pad 104 has been cleaned under conditions which allow the abrasive grains 24 and the additive 26 remaining in the grooves 130, 134 to be excessively removed, the grooves 130, 132 and the cavities 134 are filled with the deionized water 128 when the surface of the polishing pad 104 is cleaned. With the grooves 130, 132 and the cavities 134 filled with the deionized water 128, even when the polishing slurry is sufficiently fed onto the polishing pad 104 before polishing the film-to-be-polished 20, it is difficult to sufficiently replace the deionized water in the grooves 130, 132 and the cavities 134 with the polishing slurry. The deionized water filling the groves 130, 132 and the cavities 134 dilutes the polishing slurry when the film-to-be-polished 20 is polished. Then, when the film-to-be-polished 20 is polished, it is difficult to obtain desired polishing characteristics.

In the present embodiment, the surface of the polishing pad 104 is cleaned under conditions which do not excessively remove the abrasive grains 24 and the additive 26 remaining the grooves 130, 132 and the cavities 134, whereby the grooves 130, 132 and the cavities 134 are not filled with the deionized water 128. Accordingly, when the film-to-be-polished 20 is polished in a later step, the polishing slurry 128 is prevented from being diluted with the deionized water. Thus, according to the present embodiment, the film-to-be-polished 20 can be polished with desired polishing characteristics retained.

Thus, the cleaning of the surface of the polishing pad 104 is completed.

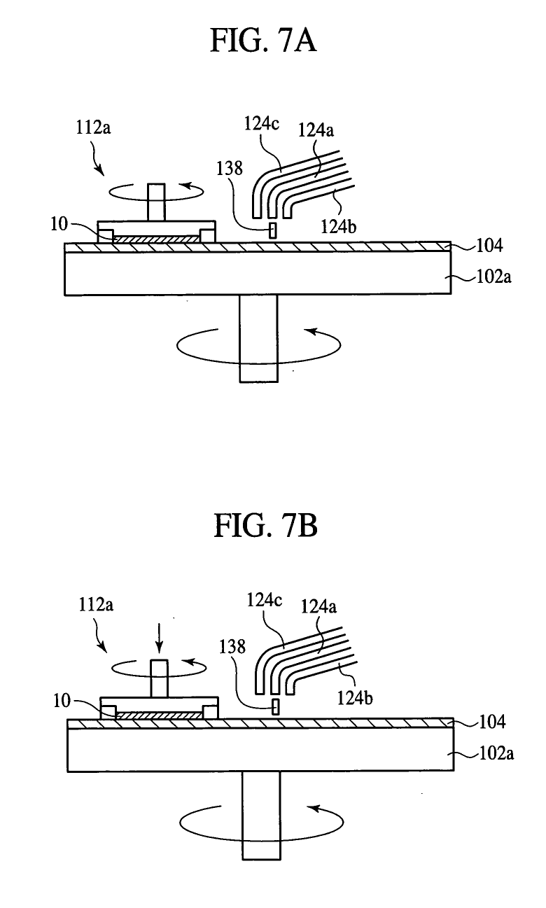

Next, the deionized water 128 present on the surface of the polishing pad 104 is replaced with the polishing slurry 138 (see FIG. 7A).

When the deionized water 128 present on the surface of the polishing pad 104 is replaced with the polishing slurry 138, the deionized water 128 present on the surface of the polishing pad 104 is replaced with the polishing slurry 138 as follows. That is, first, while the semiconductor substrate 10 is being rotated by the polishing head 112a, the polishing head 112a is lowered to bring the surface of the film-to-be-polished 20 into contact with the surface of the polishing pad 104. At this time, the polishing table 102a is rotated, and the polishing slurry 138 is fed onto the polishing pad 104 through the nozzle 124a. The polishing slurry 138 to be fed onto the polishing pad 104 will be explained later.

Conditions for replacing the deionized water present on the surface of the polishing pad 104 with the polishing slurry 138 are as exemplified below.

The flow rate of the polishing slurry 138 is, e.g., 0.1-0.3 liters/minute. The flow rate of the polishing slurry 138 is 0.135 liters/minute here.

The rotation number of the polishing table 102a is, e.g., 70-150 rotations/minute. The rotation number of the polishing table 102a is 100 rotations/minute here.

The rotation number of the polishing head 112a is, e.g., 70-150 rotations/minute. The rotation number of the polishing head 112a is 102 rotations/minute here.

The pressure for pressing the polishing head 112a against polishing pad 104, i.e., the polishing pressure is, e.g., 0 gf/cm². That is, the surface of the film-to-be-polished 20 and the surface of the polishing pad 104 are contacted with each other without pressing the surface of the film-to-be-polished 20 against the surface of the polishing pad 104.

The time in which the deionized water present on the surface of the polishing pad 104 with the polishing slurry 138 is, e.g., 1-20 second. The time in which the deionized water present on the surface of the polishing pad 104 with the polishing slurry 138 is 3 seconds here.

Conditions for replacing the deionized water 128 present on the surface of the polishing pad 104 with the polishing slurry 138 are not limited to the above and may be suitably set.

Thus, the deionized water 128 present on the surface of the polishing pad 104 is replaced with the polishing slurry 138.

Then, the film-to-be-polished 20 formed on the semiconductor substrate 10 is main-polished by CMP (see FIG. 7B).

The main polish is performed as follows. That is, while the semiconductor substrate 10 is being rotated by the polishing head 112a, the surface of the film-ti-be-polished 20 is pressed against the surface of the polishing pad 104. At this time, the polishing table 102a is rotated while the polishing slurry 138 is fed onto the polishing pad 104 through the nozzle 124a.

Conditions for the main polish are as follows.

The pressure for pressing the polishing head 112a against the polishing pad 104, i.e., the polishing pressure is, e.g., 100-500 gf/cm². The polishing pressure is 280 gf/cm² here.

The rotation number of the polishing head 112a is, e.g., 70-150 rotations/minutes. The rotation number of the polishing head 112a is 142 rotations/minute here.

The rotation number of the polishing table 102a is, e.g., 70-150 rotations/minute. The rotation number of the polishing table 102a is 140 rotations/minute.

The supply amount of the polishing slurry 138 is, e.g., 0.1-0.3 liters/minute. The supply amount of the polishing slurry 138 is 0.135 liters/minute here.

Conditions for the main polish are not limited to the above and may be suitably set.

The polishing slurry 138 contains, e.g., the abrasive grains 24 (see FIGS. 9A and 9B) and the additive 26 of a surfactant (see FIGS. 9A and 9B). In such polishing slurry, the abrasive grains 24 are, e.g., cerium oxide (ceria). Such polishing slurry contains, as the additive 26, e.g., poly(ammonium acrylate) or others. Such polishing slurry is exemplified by a polishing slurry (type: Micro Planer STI2100) by EKC Technology, Inc.

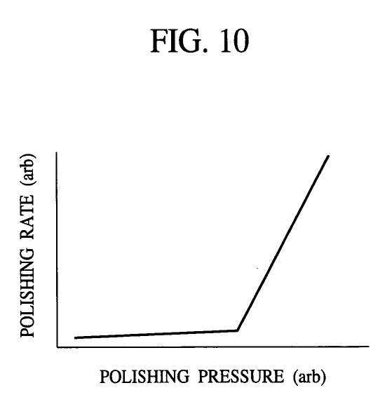

FIG. 10 is a graph of characteristics of the polishing slurry used in the present embodiment. The polishing pressures are taken on the horizontal axis, and on the vertical axis, the polishing rates are taken.

As seen in FIG. 10, the polishing slurry used in the present embodiment has lower polishing rates under lower polishing pressures than a certain polishing pressure and, under polishing pressures higher than said boundary certain polishing pressure, polishing rates which increase substantially proportionally to the polishing pressures.

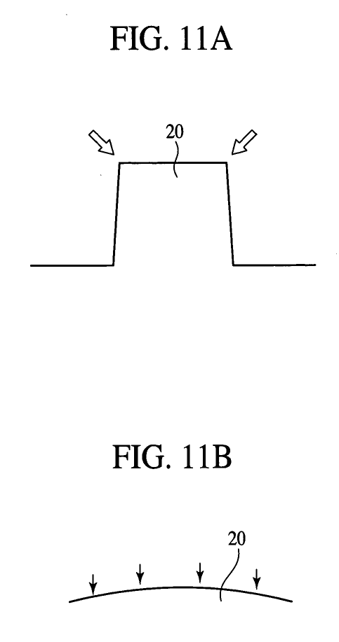

FIGS. 11A and 11B are conceptual views of the mechanism of the polishing rate change.

In the state of the surface of the film-to-be-polished 20, having a convexity as illustrated in FIG. 11A, the pressure is concentrated on the corners of the convexity of the film-to-be-polished 20, and a higher pressure is applied to the corners of the convexity of the film-to-be-polished 20. The convexity of the film-to-be-polished 20 is polished at a higher polishing rate, and the film-to-be-polished 20 is planarized at a higher polishing rate. As described above, as the polishing pressure for pressing the polishing head 112 against the polishing pad 104 is set higher, the polishing rate for the film-to-be-polished 20 tends to be higher.

As the polishing pressure for pressing the polishing head 112 against the polishing pad 104 is set higher, the polishing rate for the film-to-be-polished 20 is higher. This will be because as the polishing pressure is set higher, the surfactant contained in the polishing slurry as the additive 26 more tends to come off the corners of the convexity of the film-to-be-polished 20, and the polish for the film-to-be-polished 20 is less hindered by the surfactant.

In contrast to this, in the state of the surface of the film-to-be-polished 20, having the surface substantially planarized as illustrated in FIG. 11A, no higher pressure is applied concentratedly to a part, and a pressure applied to the film-to-be-polished 20 is generally evened. Accordingly, the polishing rate for the film-to-be-polished 20 is very low.

The low polishing rate for the film-to-be-polished 20 having a planarized surface is low. This will be because the surfactant contained in the polishing slurry as the additive 26 is not easily released and hinders the polish for the film-to-be-polished 20.

The end point of the main polish is detected, based on the drive voltage or drive current of the polishing table 102a.

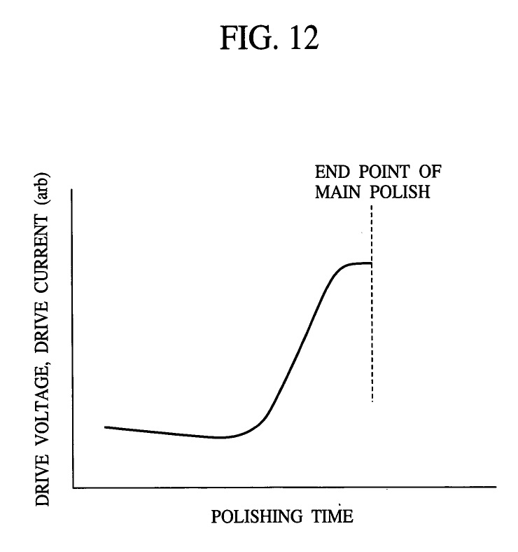

The drive voltage or the drive current of the polishing table 102a in the main polish changes as exemplified in FIG. 12. FIG. 12 is a graph conceptually showing the changes of the drive voltage or the drive current of the polishing table.

At the early stage of the polish for the film-to-be-polished 20, as illustrated in FIG. 12, the drive voltage or drive current of the polishing table 102a does not substantially change. Then, as the surface of the film-to-be-polished 20 goes on being planarized, the drive voltage or drive current of the polishing table 102a goes on rising. Then, when the surface of the film-to-be-polished 20 is substantially planarized, the drive voltage or drive current of the polishing table 102a does not substantially change. Accordingly, changes of the drive voltage or drive current per a unit time are observed to thereby detect the end point. Specifically, a time at which the change amount of the drive voltage or drive current per a unit time becomes smaller than a certain value can be the end point of the main polish.

The end point detection of the main polish is based on the drive voltage or drive current of the polishing table 102a. However, the end point detection of the main polished is not essentially based on the drive voltage or drive current and may be detected based on, e.g., torques of the polishing tables 102a. The torque of the polishing table 102a changes in the same way as the drive current and drive voltage of the polishing table 102a. The drive voltage, drive current, torque or others of the polishing head 112a are observed, whereby the end point of the main polish can be detected.

Thus, the surface of the film-to-be-polished 20 having been planarized can be detected by the above-described end point detecting method.

Thus, the surface of the film-to-be-polished 20 is planarized, and the main polish is completed.

When the main polish has been finished, the film-to-be-polished 20 remains on the silicon nitride film 14 as illustrated in FIG. 4C. The film-to-be-polished 20 remaining on the silicon nitride film 14 prohibits the etching off of the silicon nitride film 14 and the silicon oxide film 12 and must be removed. Therefore, the film-to-be-polished 20 on the silicon nitride film 14 have to be removed. Accordingly, after the main polish has been completed, the main polish is followed by the finish polish for removing the polish-to-be-polished 20 on the silicon nitride film 14.

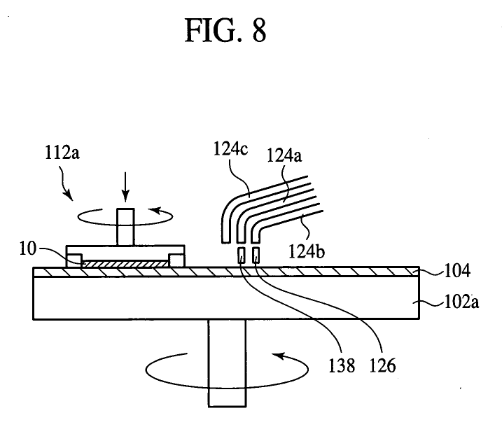

The finish polish is performed as follows. That is, while the semiconductor substrate 10 is being rotated by the polishing head 112a, the surface of the film-to-be-polished 20 is pressed against the surface of the polishing pad 104. At this time, the polishing slurry 138 is fed onto the polishing pad 104 through the nozzle 124a, and the deionized water 126 is fed onto the polishing pad 104 through the nozzle 124b. At this time, the polishing table 102a is also rotated (see FIG. 8).

When the finish polish is started, the polishing slurry 138 used in the main polish is adhering to the surface of the film-to-be-polished 20. The polishing slurry 138 is adhering also to the surface of the polishing pad 104. The additive 26 of the surfactant contained in the polishing slurry 138 is water soluble, and when the deionized water is fed, the additive 26 is removed in a short time. On the other hand, the abrasive grains 24 contained in the polishing slurry 138, which are not water soluble, cannot be removed easily and remains between the polishing pad 104 and the film-to-be-polished 20. The additive 26 has contributed to lowering the polishing rate for the film-to-be-polished 20 when the surface of the film-to-be-polished 20 has been planarized. The additive 26 is removed in a short time, but the abrasive grains 24, which contribute to the polish, remain between the polishing pad 104 and the film-to-be-polished 20 and further polishes the film-to-be-polished 20.

Conditions for the finish polish are set as follows.

The polishing pressure for pressing the polishing head 112a against the polishing pad, i.e., the polishing pressure is, e.g., 100-500 gf/cm². The polishing pressure is 210 gf/cm² here.

The supply amount of the polishing slurry 138 is, e.g., 0.05-0.3 liters/minute. The supply amount of the polishing slurry 138 is 0.1 liters/minute here.

The supply amount of the deionized water 126 is, e.g., 0.05-0.3 liters/minute. The supply amount of the deionized water is 0.25 liters/minute here.

The rotation number of the polishing head 112a is, e.g., 70-150 rotations/minute. The rotation number of the polishing head 112a is 112 rotations/minute here.

The rotation number of the polishing table 102a is, e.g., 70-150 rotations/minute. The rotation number of the polishing table 102a is 120 rotations/minute.

The period of time of the finish polish is a prescribed period of time. The period of time of the finish polish is, e.g., about 30 seconds.

Conditions for the finish polish are not limited to the above and may be suitably set.

Thus, the finish polish is completed, and the silicon oxide film 20 on the silicon nitride film 14 is removed (see FIG. 5A)

Then, the semiconductor substrate 10 is cleaned. The cleaning of the semiconductor substrate 10 is performed as exemplified below. That is, the surface of the semiconductor substrate 10 is cleaned with a brush by using, e.g., an aqueous solution of 0.3 wt % ammonium. Then, the surface of the semiconductor substrate 10 is further cleaned with a brush by using, e.g., 0.5 wt % hydrofluoric acid. Then, the semiconductor substrate 10 is rinsed with deionized water. Then, the semiconductor device 10 is dried. Thus, the semiconductor substrate 10 is cleaned.

Next, as illustrated in FIG. 5B, the silicon nitride film 14 and the silicon oxide film 12 are etched off. The device regions 22 are defined by the device isolation regions 21 of the silicon oxide film 20 buried in the trenches 18.

Then, transistor, etc. (not illustrated) are formed in the device regions 22.

Thus, the semiconductor device is fabricated by the semiconductor device fabrication method according to the present embodiment.

(Evaluation Result)

Next, the result of evaluating the semiconductor device fabrication method according to the present embodiment will be explained.

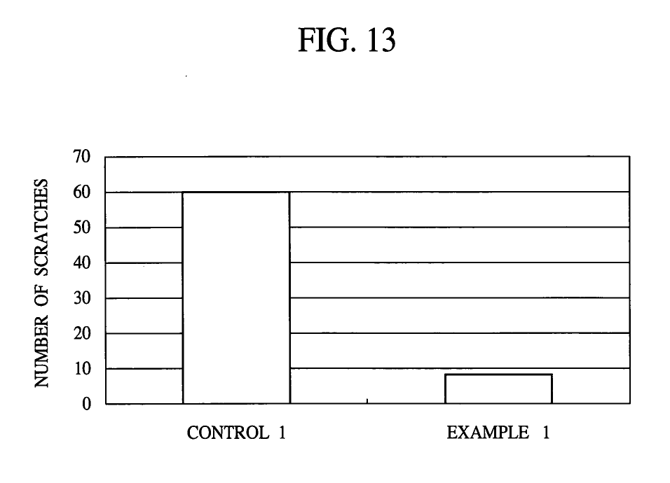

FIG. 13 is a graph (Part 1) of the numbers of scratches made in the surface of the film-to-be-polished.

Example 1 indicates the case that according to the present embodiment, the conditioning of the polishing pad 104 was performed with the deionized water being fed, then the surface of the polishing pad 104 was cleaned with the deionized water, and then the surface of the film-to-be-polished was polished. Control 1 indicates the case that the conditioning of the polishing pad 104 was performed with the deionized water being fed, and then the surface of the film-to-be-polished 20 was polished without cleaning the surface of the polishing pad 104.

As seen in FIG. 13, in Control 1, the number of scratches made in the surface of the film-to-be-polished 20 was so many as about 60.

In contrast to this, in Example 1, i.e., according to the present embodiment, the scratches made in the surface of the film-to-be-polished 20 were about 8, which was much smaller.

Based on this, it can be seen that according to the present embodiment, the number of scratches made in the surface of the film-to-be-polished 20 can be much decreased.

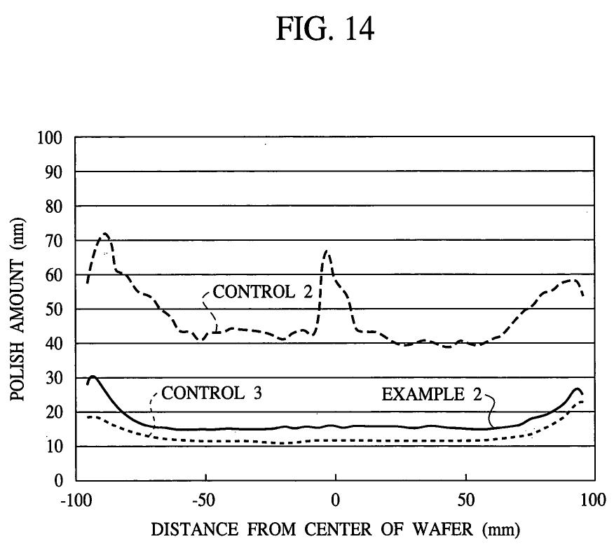

FIG. 14 is a graph of intra-plane distributions of polished amounts of the film-to-be-polished 20. Example 2 indicates the case that according to the present embodiment, the conditioning of the polishing pad 104 was performed with the deionized water being fed, then the surface of the polishing pad 104 was cleaned with the deionized water, then the deionized water present on the surface of the polishing pad 104 was replaced with the polishing slurry, and then the surface of the film-to-be-polished 20 was polished. Control 2 indicates the case that the conditioning of the polishing pad 104 is performed with the deionized water being sprayed onto the polishing pad 104 for a long time, then without cleaning the surface of the polishing pad 104, the polishing slurry was fed onto the surface of the polishing pad 104, and then the surface of the film-to-be-polished 20 was polished. Control 3 indicates the case that the conditioning of the polishing pad 104 was performed with the polishing slurry being fed, and then without cleaning the surface of the polishing pad 104, the surface of the film-to-be-polished 20 was polished. In FIG. 14, the distances from the center of the wafer are taken on the horizontal axis, and the polished amounts of the film-to-be-polished were taken on the vertical axis.

In measuring the intra-plane distributions of the polished amounts of the film-to-be-polished 20, film thicknesses of the film-to-be-polished 20 were measured sequentially along the direction of the diameter of the wafer, and intra-plane distributions of the polished amounts of the film-to-be-polished 20 is found based on differences between the measured film thickness values. In measuring the film thickness of the film-to-be-polished 20, the thin film measuring device (type: ASET-F5x) by KLA-Tencor Corporation.

In measuring the intra-plane distribution of the polish amount of the film-to-be-polished 20, the film-to-be-polished 20 was formed without forming trenches 18 in the semiconductor substrate 10, and on the film-to-be-polished 20 having the planarized surface, the polish was made. The polishing time was 1 minute.

As seen in FIG. 14, in Control 2, the polished amounts of the film-to-be-polished 20 are relatively large, and the intra-plane distribution of the polished amounts is very disuniform. The relatively large polished amounts of the film-to-be-polished 20 and the very disuniform intra-plane distribution of the polished amounts in Control 2 will be for the following reason. That is, in Control 2, when the conditioning of the polishing pad 104 is performed, the deionized water is sprayed for a long time. The abrasive grains 24 and additive 26 remaining in the grooves 130, 132 and the cavities 134 are accordingly removed by the deionized water, and the grooves 130, 132 and the cavities 134 are filled with the deionized water. In Control 2, even though the polishing slurry is fed onto the polishing pad 104 before the step of polishing the film-to-be-polished 20, the deionized water filling the grooves 130, 132 and the cavities 134 cannot be replaced by the polishing slurry. Accordingly, in Control 2, when the film-to-be-polished 20 is polished, the polishing slurry is diluted with the deionized water, and the polished amounts will become very disuniform.

In Control 3, the polished amounts of the film-to-be-polished are very small, and the intra-plane distribution of the polished amounts is relatively uniform. The small polished amounts of the film-to-be-polished 20 and the relatively uniform intra-plane distribution of the polished amounts will be for the following reason. That is, in the flat state of the surface of the film-to-be-polished 20, no high pressure is applied concentratedly to a part, and a pressure applied to the film-to-be-polished 20 is generally evened. Accordingly, the additive 26 hinders the polish for the film-to-be-polished 20, and the polishing rate for the film-to-be-polished 20 becomes very low. In Control 3, for such reason, the polished amounts of the film-to-be-polished 20 are very small, and besides, the intra-plane distribution of the polished amounts is uniform.

In Example 2, the polished amounts of the film-to-be-polished 20 are about 30 nm or below, which are relatively small, and the intra-plane distribution of the polished amounts is relatively uniform. The relatively uniform intra-plane distribution of the polished amounts in Example 2 will be for the following reason. That is, in Example 2, when the conditioning of the polishing pad 104 is performed, the deionized water is not sprayed onto the polishing pad 104, and the period of time of feeding the deionized water is relatively short. Accordingly, the polishing slurry which has remained in the grooves 130, 132 and the cavities 134 in the previous polish is not excessively removed from the grooves 130, 132 and the cavities 134, and the grooves 130, 132 and the cavities 134 are not filled with the deionized water. Thus, the deionized water on the polishing pad 104 is replaced sufficiently with the polishing slurry, by feeding of the polishing slurry before the polishing of the film-to-be-polished 20 is performed. In Example 2, the dilution of the polishing slurry with the deionized water depressed in polishing the film-to-be-polished 20, whereby the intra-plane distribution of the polished amounts can be made relatively uniform.

Based on the above, in conditioning the polishing pad 104, it is found important to condition the polishing pad 104 under conditions which do not excessively remove the polishing slurry which has remained in the grooves 130, 132 and the cavities 134 in the previous polish.

Conditions which can prevent the excessive removal of the polishing slurry remaining the grooves 130, 132 and the cavities 134 are, e.g., 1-10 seconds of the deionized water spray. Preferably, the spray amount of the deionized water is 0.2-10 liters/minute. The spray of the deionized water under such conditions can prevent the excessive removal of the polishing slurry remaining the grooves 130, 132 and the cavities 134.

The spray period of time and the spray amount of the deionized water are not limited to the above and can be suitably set.

As described above, according to the present embodiment, after the conditioning of the polishing pad 104 has been performed, the deionized water is sprayed at high-pressure onto the polishing pad 104 before the surface of the film-to-be-polished 20 is polished, whereby particles which are a factor for making scratches can be removed from the surface of the polishing pad 104 without failure. Thus, according to the present embodiment, the surface of the film-to-be-polished 20 can be polished without particles remaining on the surface of the polishing pad 104. Furthermore, the polishing pad 104 is cleaned under conditions which do not excessively remove the polishing slurry which has remained in the grooves 130, 132 and the cavities 134 in the previous polish, whereby the dilution of the polishing slurry with the deionized water in polishing the film-to-be-polished 20 can be prevented. Thus, according to the present embodiment, the generation of scratches in the surface of the film-to-be-polished 20 can be suppressed, and the film-to-be-polished 20 can be polished with desired polishing characteristics retained. Thus, the present embodiment can increase the yield of semiconductor device fabrication.

Patent Reference 1 discloses a technique of cleaning a polishing pad after a film-to-be-polished has been polished. However, in Patent Reference 1, the cleaning is not performed after the conditioning and before the polish for a film-to-be-polished. Particles produced in the conditioning cannot be removed.

Patent References 2 and 3 disclose techniques of conditioning of a polishing pad while a film-to-be-polished is being polished, i.e., conditioning a film-to-be-polished in-situ. The semiconductor device fabrication method according to the present embodiment is based on conditioning the polishing pad in the step (ex-situ) which is different from the step of polishing the film-to-be-polished. The semiconductor device fabrication method according to the present embodiment is not related to Patent References 2 and 3. In the present embodiment, the condition of the polishing pad is performed in ex-situ, because in polishing the film-to-be-polished with the polishing slurry containing the additive of a surfactant and abrasive grains, the ex-situ condition of the polishing pad often makes it impossible to obtain good polishing characteristics.

Patent References 4 to 6 disclose techniques of conditioning a polishing pad by using a high-pressure jet spray without the conditioning with a diamond disk. However, the techniques described in Patent References 4 to 6 cannot remove the surface layer of the polishing pad, which has been deformed in the polish and cannot maintain good polishing characteristics for a long period of time.

(Modification 1)

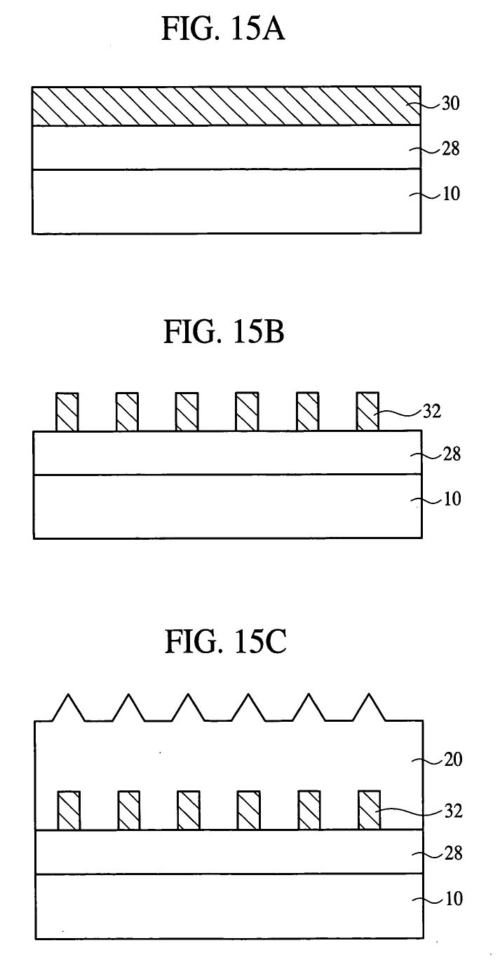

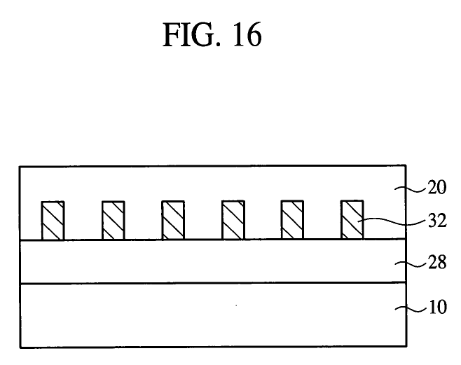

Next, the semiconductor device fabrication method according to Modification 1 of the present embodiment will be explained with reference to FIGS. 15A to 16. FIGS. 15A to 16 are sectional views of a semiconductor device in the steps of the semiconductor device fabrication method according to the present modification, which illustrate the method.

The semiconductor device fabrication method according to the present modification is characterized in that a film-to-be-polished 20 formed on interconnections 32 is polished.

First, as illustrated in FIG. 15A, an inter-layer insulation film 28 is formed on a semiconductor substrate 10 with transistors (not illustrated), etc. formed on.

Then, a layer film 30 is formed on the entire surface. The layer film 30 is to be a material of the interconnections. The layer film 30 can be formed of, e.g., a 5 nm-thickness Ti film, a 50 nm-thickness TiN film, a 300 nm-thickness Al film, a 5 nm-thickness Ti film and a 80 nm-thickness TiN film sequentially formed the latter on the former.

Then, as illustrated in FIG. 15B, the layer film 30 is patterned by photolithography. Thus, a plurality of interconnections 32 are formed of the layer film 30.

Then, as illustrated in FIG. 15C, a silicon oxide film 20 is formed on the entire surface by, e.g., high density plasma CVD. The film thickness of the silicon oxide film 20 is, e.g., about 700 nm. The silicon oxide film 20 is to be a film-to-be-polished.

Then, the process of the semiconductor device fabrication method according to the present modification, which follows hereafter is the same as that of the semiconductor device fabrication method described above with reference to FIG. 4C to FIG. 5A, and its explanation will not be repeated.

Thus, as illustrated in FIG. 16, the semiconductor device including the film-to-be-polished 20 having the planarized surface is fabricated.

As described above, the film-to-be-polished 20 may be the film-to-be-polished 20 formed on the interconnections 32.

(Modification 2)

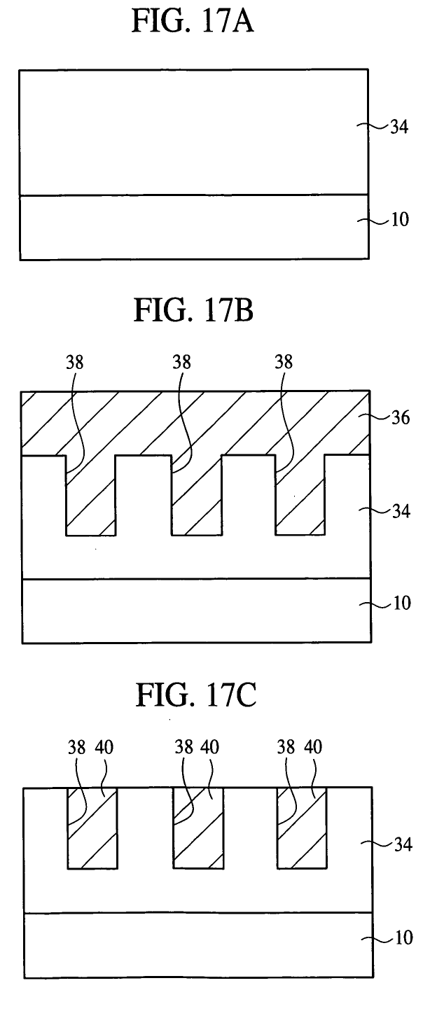

Next, the semiconductor device fabrication method according to Modification 2 of the present embodiment will be explained with reference to FIGS. 17A to 17C. FIGS. 17A to 17C are sectional views of a semiconductor device in the steps of the semiconductor device fabrication method according to the present modification, which explain the method.

The semiconductor device fabrication method according to the present modification is characterized mainly in that the film-to-be-polished 36 is formed of a metal.

First, as illustrated in FIG. 17A, an inter-layer insulation film 34 is formed on a semiconductor substrate 10 with transistors (not illustrated), etc. formed on.

Next, a photoresist film (not illustrated) is formed on the entire surface by spin coating.

Next, the photoresist film is patterned by photolithography.

Then, with the photoresist film as the mask the inter-layer insulation film 34 is etched. Thus, trenches 38 for interconnections 40 (see FIG. 17C) to be buried in or contact holes (not illustrated) for conductor plugs (not illustrated) to be buried in are formed.

Next, as illustrated in FIG. 17B, the film-to-be-polished 36 of metal is formed on the entire surface. The film-to-be-polished 36 is a layer film of, e.g., a 5 nm-thickness Ti film, a 50 nm-thickness TiN film and a 900 nm-thickness Cu film.

In the present modification, as the film-to-be-polished 36, the metal layer film is formed, but the film-to-be-polished 36 is not limited to the metal layer film and may be, e.g., a single layer of metal film.

Next, as illustrated in FIG. 17C, the film-to-be-polished 36 is polished by, e.g., CMP until the surface of the inter-layer insulation film 34 is exposed. The method for polishing the film-to-be-polished 36 by CMP is the same as the method for polishing the film-to-be-polished 20 by CMP described above, and its explanation is omitted.

In the present modification, when the film-to-be-polished 36, which is formed of metal, is polished by CMP, a polishing slurry suitable for polishing metal is used.

For example, when the film-to-be-polished 36 is formed of Cu, a polishing slurry containing abrasive grains with the additive for Cu. Such additive can be, e.g., an additive (type: CMS7303) by JSR Corporation.

When the film-to-be-polished 36 is formed of tungsten, a polishing slurry for tungsten is used. Such polishing slurry can be, e.g., a polishing slurry (type: PL5107) by Fujimi Incorporated.

The polishing slurry is not limited to such polishing slurries, and polishing slurries suitable for metals to be polished can be suitably used.

Thus, the interconnections 40 of the film-to-be-polished 36 are buried in the trenches 38. The conductor plugs (not illustrated) of metal are buried in the contact holes (not illustrated).

Thus, the film-to-be-polished 36 may be a metal layer film or a metal film.

### A Second Embodiment

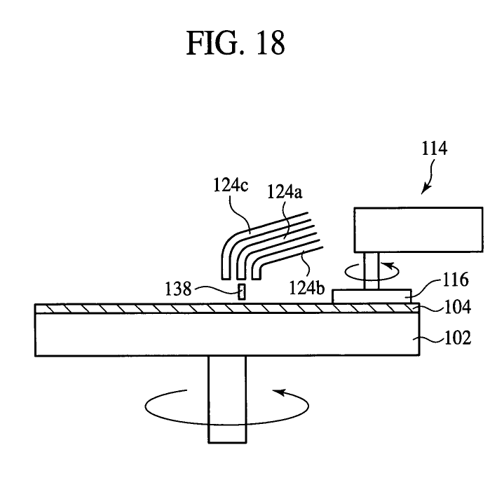

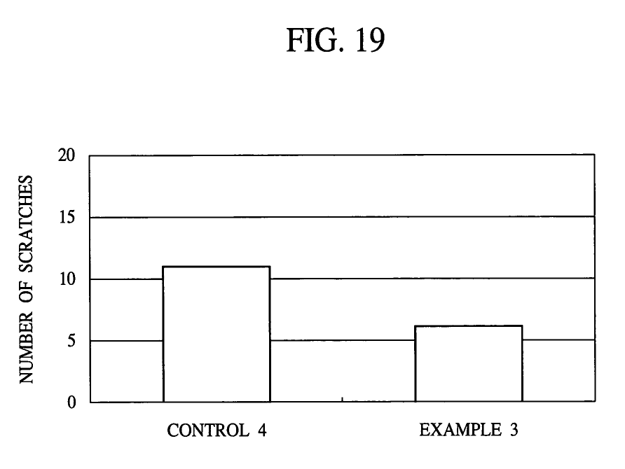

The semiconductor device fabrication method according to a second embodiment of the present invention will be explained with reference to FIGS. 18 and 19. FIG. 18 is a side view of the semiconductor device fabrication method according to the present embodiment. The same members of the present embodiment as those of the semiconductor device fabrication method according to the first embodiment illustrated in FIGS. 1 to 17C are represented by the same reference numbers not to repeat or to simplify their explanation.

The semiconductor device fabrication method according to the present embodiment is characterized mainly in that a liquid to be fed onto a polishing pad 104 when the conditioning of the polishing pad 104 is performed is a polishing slurry 138.

The steps of the process of the semiconductor device fabrication method according to the present embodiment up to the step of supporting a semiconductor substrate 10 by a polishing head 112a (see FIG. 2) including the semiconductor substrate 10 supporting step are the same as those of the semiconductor device fabrication method according to the first embodiment described above, and their explanation is omitted.

Then, the conditioning of the polishing pad 104 is performed (see FIG. 18).

The conditioning of the polishing pad 104 is performed as follows. That is, while a diamond disk 116 is being rotated, the diamond disk 116 is lowered to press the underside of the diamond disk 116 against the surface of the polishing pad 104. At this time, the polishing table 102a is rotated, and the polishing slurry 138 is fed onto the polishing pad 104 through a nozzle 124b.

Conditions for conditioning the polishing pad 104 are as exemplified below.

The supply amount of the polishing slurry 138 to be fed onto the polishing pad 104 when the conditioning is performed is, e.g., 0.1-0.3 liters/minute. The supply amount of the polishing slurry 138 is 0.2 liters/minute here.

A load for the diamond disk 116 to apply to the polishing pad 104 is, e.g., 1.3-4.6 kgf. The load for the diamond disk 116 to apply to the polishing pad 104 is 4.1 kgf here.

The rotation number of the diamond disk 116 is, e.g., 70-120 rotations/minute. The rotation number of the diamond disk 116 is 98 rotations/minute here.

The rotation number of the polishing table 102a is, e.g., 70-120 rotations/minute. The rotation number of the polishing table 102a is 105 rotations/minute.

The period of time of conditioning the polishing pad 104 is, e.g., 5-120 seconds. The period of time of conditioning the polishing pad 104 is 48 seconds here.

Conditions for conditioning the polishing pad 104 are not limited to the above and may be suitably set.

Thus, the conditioning of the surface of the polishing pad 104 is completed.

After the conditioning of the polishing pad 104 is completed, the diamond disk 116 is lifted. Thus, the diamond disk 116 is brought out of contact with the polishing pad 104.

The process of the semiconductor device fabrication method, which follows hereafter is the same as that of the semiconductor device fabrication method according to the first embodiment described above, and its explanation is omitted.

(Evaluation Result)

Next, the result of evaluating the semiconductor device fabrication method according to the present embodiment will be explained with reference to FIG. 19. FIG. 19 is a graph (Part 2) of the numbers of scratches made in the surface of the film-to-be-polished.

Example 3 indicates the case that according to the present embodiment, the conditioning of the polishing pad 104 is performed while the polishing slurry 138 is being fed, then the surface of the polishing pad 104 is cleaned with deionized water, then the polishing slurry is fed onto the polishing pad 104, and then the surface of the film-to-be-polished 20 is polished. Control 4 indicates the case that the conditioning was performed while the polishing slurry 138 is being fed, and then the surface of the film-to-be-polished 20 was polished without cleaning the surface of the polishing pad 104.

As seen in FIG. 19, in Control 4, the number of scratches made in the surface of the film-to-be-polished 20 were about 12, which is a relatively large number.

In contrast to this, in Example 3, i.e., in the present embodiment, the number of scratches made in the surface of the film-to-be-polished 20 were about 6, which is a much decreased number.

Based on this, it can be seen that according to the present embodiment, the numbers of scratches made in the surface of the film-to-be-polished 20 can be much decreased.

As described above, the polishing slurry 138 may be used as the liquid to be fed onto the polishing pad 104 when the conditioning of the polishing pad 104 is performed.

### Modified Embodiments

The present invention is not limited to the above-described embodiments and can cover other various modifications.

For example, in the first embodiment, the conditioning of the polishing pad 104 is performed with the deionized water 126 alone being fed onto the polishing pad 104. The liquid to be fed when the conditioning of the polishing pad 104 is performed is not limited to deionized water. In the second embodiment, the conditioning of the polishing pad 104 is performed with the polishing slurry 138 alone being fed onto the polishing pad 104. However, the liquid to be fed when the conditioning of the polishing pad 104 is performed is not limited to the polishing slurry 138. For example, when the conditioning of the polishing pad 104 is perforemd, both the deionized water 126 and the polishing slurry 138 may be fed onto the polishing pad 104, and in this case, the deionized water is fed onto the polishing pad 104 through the nozzle 124b, and through the nozzle 124a the polishing slurry is fed onto the polishing pad 104. When the conditioning of the polishing pad 104 is performed, a mixture of the polishing slurry 138 and the deionized water 126, i.e., the polishing slurry diluted with the deionized water may be fed onto the polishing pad 104.

In the second embodiment, the film-to-be-polished 20 formed on the semiconductor substrate 10 with the trenches 18 formed in is polished. However, the film-to-be-polished 20 formed on the semiconductor substrate 10 with the interconnections 32 formed on may be polished (see FIGS. 15A to 16).

In the second embodiment, the film-to-be-polished 20 of an insulation film is polished but is not essentially the insulation film. For example, the film-to-be-polished 36 of, e.g., metal film or metal layer film may be polished (see FIGS. 17A to 17C).

In the above-described embodiments, the polishing slurry 138 containing the abrasive grains 24 of cerium oxide (ceria) is used. However, the abrasive grains 24 contained in the polishing slurry 138 are not essentially formed of cerium oxide. For example, the polishing slurry containing abrasive grains of silicon oxide (silica) may be used. Such polishing slurry can be, e.g., KS-S-210 by Kao Corporation.

In the above-described embodiments, the polishing slurry containing the additive of a surfactant and the abrasive grains is used. However, the polishing slurry to be fed onto the polishing pad is not limited to such polishing slurry. For example, the polishing slurry to be fed onto the polishing pad can be a polishing slurry containing abrasive grains of silica and the additive of KOH may be used. A polishing slurry containing no abrasive grains may be used.

In the above-described embodiments, the present invention is applied to forming device isolation regions by STI. However, the present invention is not applied essentially to forming device isolation regions and is widely applicable to polishing the surfaces of films-to-be-polished.

1. A semiconductor device fabrication method comprising the steps of:
conditioning the surface of a polishing pad while a liquid is being fed onto the polishing pad;
spraying water onto the polishing pad to clean the surface of the polishing pad after the conditioning of the surface of the polishing pad has been performed; and
polishing the surface of the film-to-be-polished formed over the semiconductor substrate with the polishing pad while the polishing slurry being fed onto the polishing pad to planarize the surface of the film-to-be-polished, after the surface of the polishing pad has been cleaned.

2. A semiconductor device fabrication method according to claim 1, further comprising, after the step of cleaning the surface of the polishing pad and before the step of polishing the surface of the film-to-be-polished,
the step of feeding the polishing slurry onto the polishing pad to replace the water present on the surface of the polishing pad with the polishing slurry.

3. A semiconductor device fabrication method according to claim 1, wherein
in the step of conditioning the surface of the polishing pad, the conditioning of the surface of the polishing pad is performed while the water is being fed onto the polishing pad.

4. A semiconductor device fabrication method according to claim 1, wherein
in the step of conditioning the surface of the polishing pad, the conditioning of the surface of the polishing pad is performed while the polishing slurry is being fed onto the polishing pad.

5. A semiconductor device fabrication method according to claim 1, wherein
in the step of conditioning the surface of the polishing pad, the conditioning of the surface of the polishing pad is performed while water and the polishing slurry are being fed onto the polishing pad.

6. A semiconductor device fabrication method according to claim 1, wherein
in the step of conditioning the surface of the polishing pad, the conditioning of the surface of the polishing pad is performed while a mixture of water and the polishing slurry is being fed onto the polishing pad.

7. A semiconductor device fabrication method according to claim 1, wherein
in the step of cleaning the surface of the polishing pad, the water is sprayed for a 1 to 10 second spraying period of time to clean the surface of the polishing pad.

8. A semiconductor device fabrication method according to claim 1, wherein
in the step of cleaning the surface of the polishing pad, the water is sprayed at a 0.2-10 liters/minute spray amount to clean the surface of the polishing pad.

9. A semiconductor device fabrication method according to claim 1, further comprising, before the step of polishing the surface of the film-to-be-polished, the steps of:
forming over the semiconductor substrate an insulation film having etching characteristics different from those of the film-to-be-polished;
forming openings in the insulation film;
etching the semiconductor substrate with the insulation film as a mask to form trenches in the semiconductor substrate; and
forming the film-to-be-polished in the trenches and over the insulation film.

10. A semiconductor device fabrication method according to claim 1, further comprising, before the step of polishing the surface of the film-to-be-polished, the steps of:
forming interconnections over the semiconductor substrate; and
forming the film-to-be-polished over the interconnections and the semiconductor substrate.

11. A semiconductor device fabrication method according to claim 1, wherein
the film-to-be-polished is an insulation film.

12. A semiconductor device fabrication method according to claim 1, wherein
the film-to-be-polished is a metal film or a metal layer film.

13. A semiconductor device fabrication method according to claim 1, wherein
the polishing slurry contains abrasive grains and additive of a surfactant.

14. A semiconductor device fabrication method according to claim 13, wherein
the abrasive grains contain cerium oxide or silicon oxide.

15. A semiconductor device fabrication method according to claim 13, wherein
the additive contains poly(ammonium acrylate).
